(19) United States
(12) Patent Application Publication
(10) Pub. No.: US 2010/0053911 A1
(43) Pub. Date: Mar. 4, 2010

(54) Extruded Housing for Hand-Held Device with a cap for covering two or more adjacent sides

(75) Inventors: Gary R. Weiss, Buffalo Grove, IL (US); Joseph L. Allore, Mundelein, IL (US); Jason P. Wojack, Libertyville, IL (US)

Correspondence Address: MOTOROLA INC, 600 NORTH US HIGHWAY 45, W4 - 39Q, LIBERTYVILLE, IL, 60048-5343, US

(73) Assignee: MOTOROLA INC., Libertyville, IL (US)

(21) Appl. No.: 12/269,570

(22) Filed: Nov. 12, 2008

Related U.S. Application Data
(60) Provisional application No. 61/093,352, filed on Aug. 31, 2008.

(51) Int. Cl. H05K 5/02; H05K 7/00; H05K 5/00

(52) U.S. Cl. 361/752; 428/119; 428/34.1; 361/679.01

(57) ABSTRACT

A housing for a hand-held electronic device is provided. The housing includes an extruded element having a length and a profile, the length corresponding to a distance that the extruded element extends in the direction of extrusion, and the profile corresponding to a cross-section of the element, which is perpendicular to the direction of extrusion. The profile of the extruded element has a major axis which extends a distance in a first direction and a minor axis which extends a distance in a second direction which is substantially perpendicular to the first direction. The amount of the distance that the profile extends in the direction of the major axis is greater than the amount of the distance that the profile extends in the direction of the minor axis. The length of the extruded element in the direction of extrusion is less than the amount of the distance that the profile extends in the direction of the major axis.

### CROSS REFERENCE TO RELATED APPLICATIONS

This application claims priority from a U.S. Provisional Patent Application Ser. No. 61/093,352, filed Aug. 31, 2008.

### FIELD OF THE INVENTION

The present invention relates generally to a housing for a hand-held electronic device, and more particularly, to a housing including an extruded element having an opening in the profile which defines an interior space.

### BACKGROUND OF THE INVENTION

Hand-held electronic devices have often been made from two separately formed halves of a housing, a front half and a back half, which are coupled together with one or more fasteners, within which the electrical and mechanical components forming the device are placed. Often times, each of the front half and the back half are formed from plastic or other material using an injection molding process, which enables considerable freedom in incorporating diverse sizes and shapes, and which can be used to produce various functional and/or aesthetic effects. Generally, the desired sizes and shapes, and their corresponding arrangement are incorporated into the shape of a mold. The mold is then used to produce the parts.

More recently an increasing amount of housings are being seen, which are being made from materials other than plastics, such as various metals and metal alloys, where the use of metal materials have often been accompanied by still further manufacturing techniques for similarly producing separately formed halves, which are then coupled together. In the case of metals and metal alloys, various techniques including forging, and/or stamping and forming have often been used to produce components used in forming the housings.

The movement toward an increasing amounts of metal in the housings has been precipitated in part due to the decrease in the overall size of devices, while the size of displays, keypads, and other components have alternatively increased in size. This has resulted in less material (i.e. reduced device volume) being used in the formation of the housing, as well as the support structures within and/or forming part of the housing. Correspondingly, the material used to form the housing and/or the corresponding support structures have had to be formed from stronger materials able to withstand an ever increasing load per unit measure. This in turn has facilitated the increasing use of manufacturing processes, which are consistent with the more recently predominant materials being used.

With molded, forged and stamped parts, tooling used in economically producing large volumes of the parts tends to be very specific to a particular design, such that if changes need to be made to the design, often times corresponding changes need to made to the associated tooling. For example, if the parts which are being molded need to be changed, the mold from which the parts are produced would often similarly need to be changed. In some instances, an existing mold might be able to be modified to accommodate a particular change. In other instances, new molds might need to be produced.

Some manufacturing processes for housings for use in hand-held electronic devices have more recently involved the use of extruded materials. Extruded materials typically involve a manufacturing method where an amount of material is pushed or drawn through a die, thereby producing a formed element, which has a generally uniform profile at varying points along the length of the extruded element in the direction of extrusion. More specifically, the formed element generally has a uniform cross sectional shape which is defined by the size and the shape of the openings in the die through which material is pushed or drawn. In addition to using the die to define the outer cross sectional shape, hollow sections within the shape can similarly be formed, for example, by placing a pin or piercing mandrel inside the die. Traditionally, extrusions have been used in applications where an element having long, straight and generally uniform shapes are desired. For elements having significant variations along the length of the element, extrusions have typically been avoided.

Recent extruded elements used in the formation of a housing have included an extrusion having one piece continuous outer profile, which is used to form both the front, back and sides of the device, one such example includes Jorgensen, US Published Patent Application No. 2007/0265028. Such a construction can result in enhanced structural strength, in so far as the front, back and sides are formed as part of a one piece construction. A hollow section is formed in the extruded element having an opening at the beginning and end of the extrusion, which has generally corresponded to a top and bottom, within which mechanical and electronic components can be placed. In some instances openings will be cut into the sidewall of the extruded element along the length of the same to provide more direct access to some of the internally placed and appropriately aligned mechanical and electronic components. After the components have been placed within the housing, the openings at the ends of the extrusion are generally capped.

In such an instance, the appearance of the housing is generally very uniform (i.e. generally does not vary) along the length of the extrusion. To date, such a construction has resulted in housings which have very limited amounts of variability along the length of the extrusion, and housings which include an extruded element having a width that substantially corresponds to the full width of the respective portion of the housing. While such a style can be very clean and uniform, sometimes such a style can be very plain. In some instances, it can be very difficult to deviate from such a style even when function and/or aesthetics would prefer such a deviation, which limits the type of housings that have historically been produced through such a manufacturing process.

Increasingly, there has been a need to provide access for the purpose of interacting with and/or inserting and removing by the user some of the device's circuit elements and interfaces, which are at least partially positioned within the internal space of the device. While an opening at each of the top and bottom provides some degree of access, the size, position, and shape of the top and bottom of the device and correspondingly any opening provided via the top and bottom for providing access to the device's internal space as part of the typical extruded housing is generally limited. Furthermore, the top and the bottom of the handheld device is often the preferred site of some of the device's other structure and circuitry, which can sometimes interfere with the insertion and removal of circuit elements for which more ready access by the user might be desirable via any opening proximate the same location. For example, an antenna that supports the transmission and reception of electromagnetic energy is often positioned proximate the top of the device. Similarly for some styles of hand-held electronic devices, mechanical structures, which support a hinged coupling of a two part housing, are commonly positioned proximate the top of the device.

Furthermore, areas of user interaction are often more readily associated with the side of the device. This corresponds to the positions where a user's hand or fingers are more likely to intersect with the device, while more comfortably holding the same. However, in order to support the side positioning of interactive features, openings sometimes need to be provided in the side of the device to provide access to device components at least partially positioned within the internal space. In at least some of the more traditional extruded housings, any side access to internally positioned components is generally provided via openings that are separately cut through the side of the extruded element. Alternatively, an extrusion might not have a profile having a closed circumference

The present inventors have recognized that it would be beneficial if the direction of extrusion of the extruded element, and correspondingly the position of the opening in the profile used for forming the internal space of a housing for an electronic device could be repositioned so as to provide greater side access without compromising the structural strength of the extruded element, where a user is more likely to interface with the device, and where a larger area for supporting an opening would more readily provide access to the internal space of the device.

### SUMMARY OF THE INVENTION

The present invention provides a housing for a hand-held electronic device. The housing includes an extruded element having a length and a profile, the length corresponding to a distance that the extruded element extends in the direction of extrusion, and the profile corresponding to a cross-section of the element, which is perpendicular to the direction of extrusion. The profile of the extruded element has a major axis which extends a distance in a first direction and a minor axis which extends a distance in a second direction which is substantially perpendicular to the first direction. The amount of the distance that the profile extends in the direction of the major axis is greater than the amount of the distance that the profile extends in the direction of the minor axis. The length of the extruded element in the direction of extrusion is less than the amount of the distance that the profile extends in the direction of the major axis.

In at least one embodiment, the profile has a substantially continuous outer boundary, corresponding to an outer perimeter of the profile, which extends the length of the extrusion, defining a substantially tubular member having an internal space, which extends the length of the extruded element in the direction of the extrusion and has an opening at each of the beginning and the end of the extrusion.

In at least a further embodiment, the internal space includes one or more internal walls, which subdivide the internal space.

In at least a still further embodiment, one or more of the openings of the extruded element at each of the beginning and the end of the extrusion provides access to electronic circuitry located within the internal space of the extruded element.

In at least a still further embodiment, the housing further includes a first side cap coupled to the extruded element proximate the opening at the beginning of the extrusion and a second side cap coupled to the extruded element proximate the opening at the end of the extrusion. In at least some of these instances at least one of the first side cap and the second side cap includes one or more connectors for receiving and making electrical connection with an electronic circuit substrate.

The present invention further provides a hand-held electronic device including a housing. The housing of the hand-held electronic device includes an extruded element having a length and a profile, the length corresponding to a distance that the extruded element extends in the direction of extrusion, and the profile corresponding to a cross-section of the element, which is perpendicular to the direction of extrusion. The profile of the extruded element has a major axis which extends a distance in a first direction and a minor axis which extends a distance in a second direction which is substantially perpendicular to the first direction. The amount of the distance that the profile extends in the direction of the major axis is greater than the amount of the distance that the profile extends in the direction of the minor axis. The length of the extruded element in the direction of extrusion is less than the amount of the distance that the profile extends in the direction of the major axis.

### BRIEF DESCRIPTION OF THE DRAWINGS

FIG. 1 is a perspective view of an exemplary extruded element for use as a housing for a hand-held electronic device, in accordance with at least one aspect of the present invention;

FIG. 2 is a perspective view of the exemplary extruded element and a corresponding carrier frame for use in supporting the insertion of electrical and mechanical elements into the extruded element of the type, illustrated in FIG. 1;

FIG. 3 is a perspective view of an exemplary extruded element adapted to receive one or more circuit substrates, as well as one or more side caps, in accordance with at least one aspect of the present invention;

FIG. 4 is a partial cutaway bottom or top view of the extruded element illustrated in FIG. 3, which illustrates an exemplary routing of electrical conductors integrated as part of the one or more side caps;

FIG. 5 is a front plan view of a further exemplary extruded element, which is alternatively adapted to receive multiple circuit substrates arranged side by side; and

FIG. 6 is a side plan view of an exemplary side panel, illustrating an exemplary placement of one or more electrical, mechanical and/or electro-mechanical components, and/or exemplary location for providing access between the space internal to the device and space external to the device for the same one or more electrical, mechanical and/or electro-mechanical components.

### DETAILED DESCRIPTION OF THE PREFERRED EMBODIMENT(S)

While the present invention is susceptible of embodiment in various forms, there is shown in the drawings and will hereinafter be described presently preferred embodiments with the understanding that the present disclosure is to be considered an exemplification of the invention and is not intended to limit the invention to the specific embodiments illustrated.

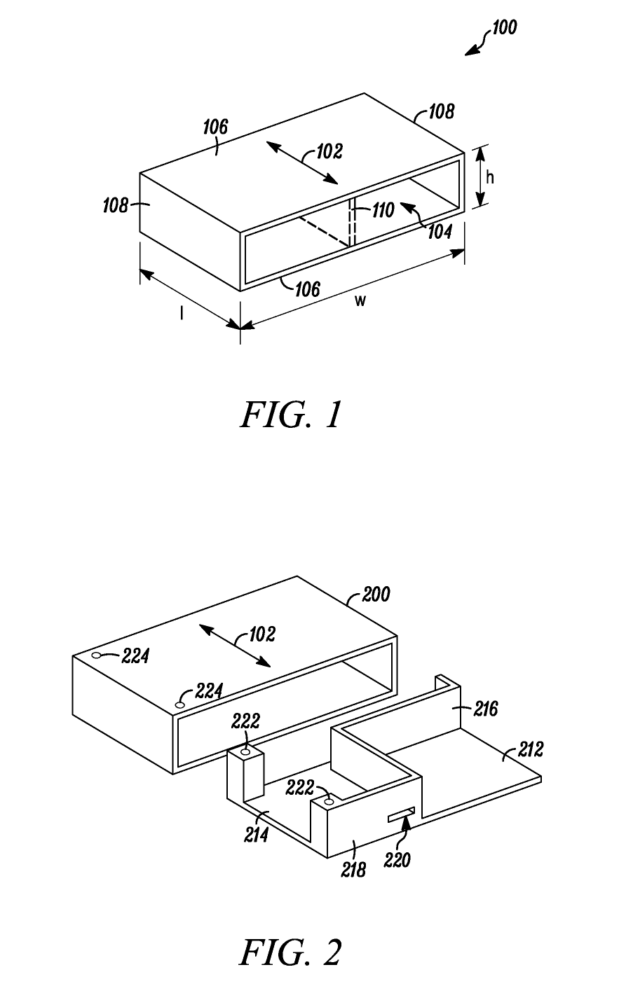

FIG. 1 illustrates a perspective view of an exemplary extruded element 100 for use as a housing for a hand-held electronic device, in accordance with at least one aspect of the present invention. In connection with the illustrated embodiment, an arrow 102 defines a direction of extrusion. An extruded element generally has a profile which is perpendicular to the direction of extrusion, that is largely uniform and defined by the size and shape of an opening in a die through which the extruded material is pushed and/or drawn. In the illustrated embodiment, the profile is represented by the surface illustrated in FIG. 1, which has a rectangular opening 104, where the rectangular opening 104 defines one end of an interior space that runs a distance 1, along the length of the extruded element 100. In the illustrated embodiment, the profile extends a distance h in a first direction corresponding to a height of the profile, and extends a distance w in a second direction corresponding to a width of the profile, where the width extends in a direction that is generally perpendicular to the direction of the height.

In the illustrated embodiment, the direction corresponding to the width represents the major axis of the profile, and the direction corresponding to the height represents the minor axis, as the distance that the profile extends in the direction of the width is greater than the distance that the profile extends in the direction of the height. In addition to the distance w that the profile extends in the direction of the width being greater than the distance h that the profile extends in the direction of the height, the distance w that the profile extends in the direction of the width is similarly greater than the distance 1 that the extruded element 100 extends in the direction of extrusion. Alternatively, the distance h that the extruded element 100 extends in the direction of the height, is less than the distance 1 that the extruded element 100 extends in the direction of extrusion.

In turn, the front and back facings 106 of the device generally correspond to the surfaces defined by the two largest distances, namely the length and the width. The top and the bottom facings 108 of the device generally correspond to the surfaces defined by the two smallest distances, namely the length and the height.

As a result, in the illustrated embodiment, the rectangular opening 104, which forms the interior space as it extends the length of the extrusion, has an opening size which generally exceeds the depth of the interior space. Furthermore, such a relationship between the length, height and width generally positions the opening which provides access to the internal space at each of the respective sides of the device. In turn, this enables a larger opening across which access points can be positioned for the purpose of interacting with and/or inserting and removing by the user at least some of the device's circuit elements and interface connectors. Examples of electrical and/or mechanical circuit elements that can be accessed this way includes displays, keypads, sensors, user actuatable switches, imaging assemblies, microphones, transducers, speakers, antennas, processor circuits, memory circuits, transmitter circuits, receiver circuits, power management circuits, power sources (i.e. batteries), jacks, connector ports, etc. The types of circuit elements that might be incorporated into the extruded element, which forms at least part of a housing for a hand-held electronic device will largely depend upon the type of the device. Examples of different types of hand-held electronic devices with which the present extruded element in accordance with the present invention might be suitable include radio frequency (i.e. cellular) telephones, media (i.e. music) players, personal digital assistants, portable video gaming devices, cameras, and/or remote controls, each one of which will potentially have a different set of circuit elements with which it is desirable for the user to interact. Nevertheless, one skilled in the art will recognize that the extruded element of the present invention is suitable for use with other types of hand-held electronic devices without departing from the teachings of the present invention.

The greater width of the extruded element in conjunction with an extruded element having decreased depth, or length in the direction of extrusion, provides an increased ability to provide direct access through the side opening for a greater number of circuit elements, with fewer circuit elements being positioned behind other circuit elements, which might limit the ability to more directly access the same. Additionally, the already present opening readily enables the circuit elements to be positioned proximate and accessed via the already present opening in the side of the device, which is often consistent with the manner in which the user would comfortably hold the device, and more comfortably interact with its features.

In at least some instances, it is possible that the internal space could be subdivided by the inclusion of one or more internal walls without material affecting the amount of available open surface area used to access the internal space compared to the overall amount of internal space. In turn, the internal wall might provide additional support for the overall structure. An example of one possible manner of implementing an internal wall could be facilitated through a feature included as part of the extruded profile. In at least one embodiment, by subdividing the opening in the profile of the extrusion into multiple openings, a wall that runs the length of the extrusion and separates the interior space into multiple compartments is provided. An example of such a wall 110 is illustrated in FIG. 1, using dashed lines.

It is further possible that a structure allowing for the subdivision of the internal space, including one or more walls, could be provided via a carrier frame. Furthermore, the carrier frame could be pre-populated with the circuit elements, which are intended to be placed inside of the extruded housing, prior to the carrier frame being placed inside of the extruded element 100, which might facilitate a more preferred form of assembly. FIG. 2 illustrates a perspective view of the exemplary extruded element 200 and a corresponding carrier frame 212 for use in supporting the insertion of electrical and mechanical elements into the extruded element of a similar type, illustrated in FIG. 1. The carrier frame includes a base 214 and one or more wall segments 216, which in turn can be used to provide additional internal structure, as well as can be used to subdivide the internal space. In addition to providing additional internal physical support structure, some of the wall segments 216, might additionally provide and/or support the inclusion of shielding which inhibits the propagation of energy that might be being radiated from one or more of the included circuit elements.

In some instances, the carrier frame structure might support internal walls, that help define various compartments for receiving very specific types of circuit elements. For example, some of the carrier frame structure might serve to define the size and shape of a battery compartment. In other instances, some of the frame structure might used to at least partially close the access opening 104 in the side of the extruded element. Still further where the frame structure serves to at least partially close the access opening 104, the frame structure might include access features that are used to better define the access openings for supporting user accessible circuit elements. For example, wall segment 218 might include a slot 220 for receiving a memory card or user (i.e. subscriber) identity module.

In the illustrated embodiment, the carrier frame 212 additionally includes structure for more securely attaching the carrier frame 212 to the extruded element 200, after the carrier frame 212 has been inserted into the internal space. More specifically, the carrier frame includes holes 222 that might be threaded for receiving a fastener (not shown), such as a screw. Corresponding holes 224 that might be machined into the extruded element 200 could be used to facilitate the more secure attachment of the carrier frame 212 to the extruded element 200.

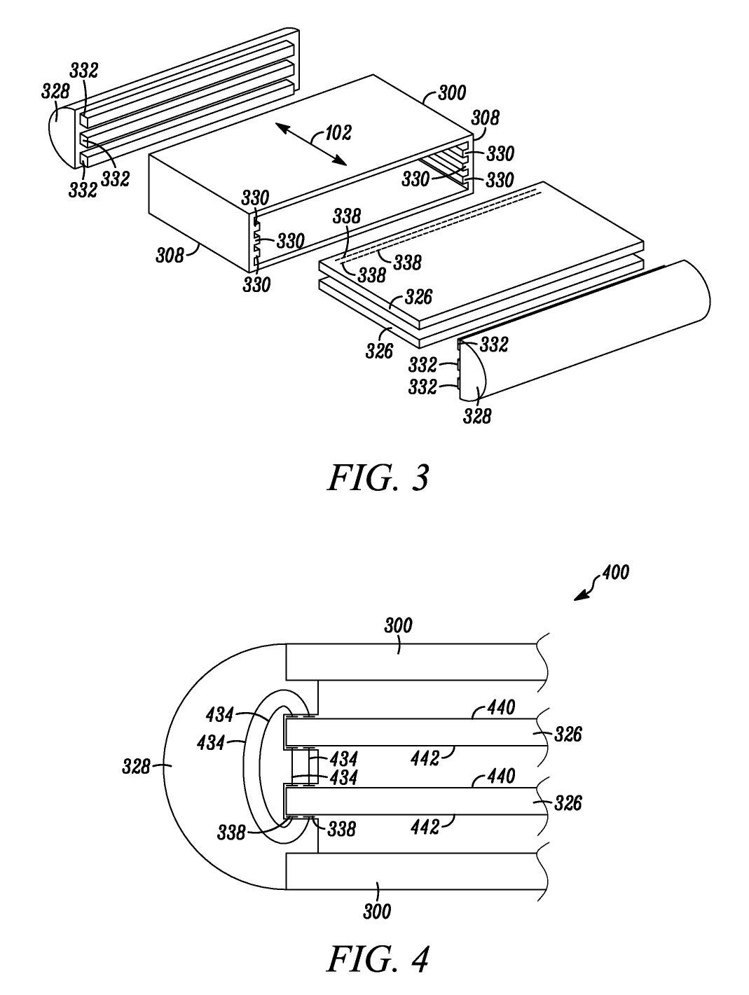

In addition to, or as an alternative to the use of a carrier frame 212, the extruded element 200 might be adapted to receive one or more circuit substrates. FIG. 3 illustrates a perspective view of an exemplary extruded element 300 adapted to receive one or more circuit substrates 326, as well as one or more side caps 328, in accordance with at least one aspect of the present invention. In the illustrated embodiment, the extruded element 300 is similar to the extruded element illustrated in FIG. 1, with the exception that a set of rails 330 has been provided in the top and bottom sidewalls 308 of the extruded element 300. In the illustrated embodiment, given the direction of extrusion 102, it is possible to incorporate the rails 330 in the profile of the extruded element 300.

The rails 330 are spaced as to enable suitably sized circuit substrates 326 to be slid into and captivated within a corresponding pair of predetermined slots formed from a pair of adjacent rails 330 formed as part of the extruded element 308. One or more end caps 328, sometimes referred to as extrusion covers, can be used to close the side openings after the circuit substrates 326 have been received within the extruded element 300. In the illustrated embodiment, the end caps 328 similarly include rail type features 332 that have been incorporated as part of the structure of the end caps.

In addition to serving to close the side opening, in at least the illustrated embodiment, at least one of the end caps 328 further incorporates connector couplings which provide an electrical coupling between the illustrated pair of circuit substrates 326. FIG. 4 illustrates a partial cutaway bottom or top plan view 400 of the extruded element illustrated in FIG. 3, which illustrates the exemplary routing of electrical conductors 434 integrated as part of the one or more side end caps 328. In the illustrated embodiment, the end cap supports multiple rows of conductors 434 and corresponding contact pads 338 (FIG. 3), associated with each of the circuit substrates 326. In addition to supporting multiple rows of pads 338, which are located along the side of the circuit substrate 326, the end cap further supports contact pads 338 which are located on both sides of the circuit substrate. In fact, in accordance with at least the illustrated embodiment, in order to simplify the routing of the electrical conductors 434 within the end cap 328, contact pads associated with the top surface 440 of one of the circuit substrates 326 is coupled to contact pads 338 associated with the bottom surface 442 of the other circuit substrate 326. The electrical conductors 434 enable electrical signal from one of the circuit substrates 326 to be conveyed to the other one of the circuit substrates.

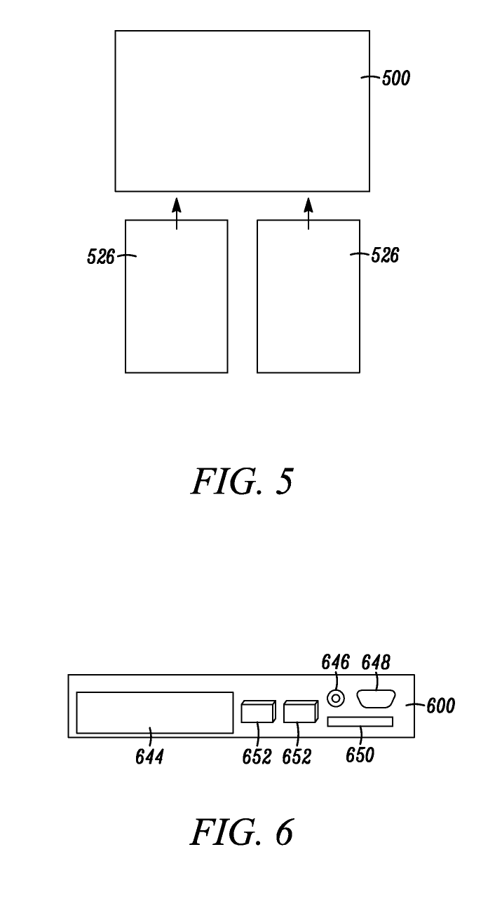

FIG. 5 illustrates a front plan view of a further exemplary extruded element 500, which is alternatively adapted to receive multiple circuit substrates 526 that are arranged side by side. Whereas the circuit substrates 326, illustrated in FIG. 3, are arranged with a vertical offset in a direction previously identified in FIG. 1 corresponding to height, the circuit substrates 526 are arranged with an alternative and/or additional horizontal offset in a direction corresponding to width. This arrangement may be appropriate in circumstances where the electronic circuitry being incorporated into the hand-held electronic device is more modular, and therefore may require a greater number of smaller substrates. The present arrangement may further be beneficial in instances where the extruded profile incorporates an internal wall, such as the optional internal wall 110 illustrated in FIG. 1 using dashed lines, in which case a larger substrate might not fit in the available subdivided space.

Where the circuit substrates 526 are arranged side by side, the end caps 328 can continue to provide electrical connectivity between circuit substrates. However instead of the electrical conductors that are incorporated in the end caps conveying signals in a vertical fashion (i.e. heightwise direction), the electrical conductors would largely convey the signals in a more horizontal (i.e. widthwise direction). Furthermore, such connectivity may be even more beneficial in instances where an internal wall 110 within the interior space of the extruded element 500 limits access between the different halves of the divided interior space, and any corresponding circuit substrates existing in alternative halves of the divided interior space.

FIG. 6 is a side plan view of an exemplary side panel 600, illustrating an exemplary placement of one or more electrical, mechanical and/or electro-mechanical components, and/or exemplary location for providing access between the space internal to the device and the space external to the device for one or more electrical, mechanical and/or electro-mechanical components. In essence, FIG. 6 illustrates an access panel in place of an end cap 328, which might be used to close the opening at one end of the extruded element 100, while providing a cleaner look that still allows user access to the interior space for interacting with and/or removing/inserting the electrical and/or mechanical circuit elements that will be or are at least partially present in the interior space.

For example in at least some embodiments, the control panel 600 might include a space 644 for removing or inserting a battery, where a battery door might close or seal the opening during times in which the battery is neither being inserted nor removed. By enabling the battery to be inserted or removed via a side opening, battery doors which have commonly been located on the back surface of the device can be avoided. By avoiding a back surface battery door, the external surface space which has sometimes been previously associated with the battery door can be recaptured to support the placement of a further user interface, such as a touch sensitive user interface area or strip, keypad or display.

The control panel 600 might further provide for various ports, including port 646, which might be an audio connector port such as for a hardwired headset connection, or a port for supporting the connection of a test fixture. Examples of still further types of ports might include a more generic peripheral bus port 648, such as a USB connector port, where in some instances it may be possible to recharge the device through such a port. The control panel 600 might further include a slot 650 for receiving a memory card or a subscriber identity module. In the illustrated embodiment, the control panel additionally includes a pair of user actuatable switches 652 which can be selectively actuated to provide a manner in which the user might direct the operation of the device.

By providing an extruded element 100, where the profile and the corresponding opening in the profile coincides with a side surface having a larger amount of surface area, it is possible to support a more comprehensive and more varied interface for the user for access with the internal space of the device, while minimizing the number of openings which might otherwise need to be made in the side of the extruded element 100. While FIG. 6, illustrates one possible layout for a side access panel, one skilled in the art will readily recognize that the type of access openings, and their corresponding arrangements could be readily modified to suit the particular needs of a particular or a particular type of device without departing from the teachings of the present invention.

While the preferred embodiments of the invention have been illustrated and described, it is to be understood that the invention is not so limited. Numerous modifications, changes, variations, substitutions and equivalents will occur to those skilled in the art without departing from the spirit and scope of the present invention as defined by the appended claims.

What is claimed is:

1. A housing for a hand-held electronic device comprising:
an extruded element having a length and a profile, the length corresponding to a distance that the extruded element extends in the direction of extrusion, and the profile corresponding to a cross-section of the element, which is perpendicular to the direction of extrusion;
wherein the profile of the extruded element has a major axis which extends a distance in a first direction and a minor axis which extends a distance in a second direction which is substantially perpendicular to the first direction, and wherein the amount of the distance that the profile extends in the direction of the major axis is greater than the amount of the distance that the profile extends in the direction of the minor axis
wherein the length of the extruded element in the direction of extrusion is less than the amount of the distance that the profile extends in the direction of the major axis.

2. A housing for a hand-held electronic device in accordance with claim 1, wherein the profile has a substantially continuous outer boundary, corresponding to an outer perimeter of the profile, which extends the length of the extrusion, defining a substantially tubular member having an internal space, which extends the length of the extruded element in the direction of the extrusion and has an opening at each of the beginning and the end of the extrusion.

3. A housing for a hand-held electronic device in accordance with claim 2, wherein the substantially tubular member encircles the internal space.

4. A housing for a hand-held electronic device in accordance with claim 2, wherein the internal space includes one or more internal walls, which subdivide the internal space.

5. A housing for a hand-held electronic device in accordance with claim 2, further comprising a first side cap coupled to the extruded element proximate the opening at the beginning of the extrusion and a second side cap coupled to the extruded element proximate the opening at the end of the extrusion.

6. A housing for a hand-held electronic device in accordance with claim 5, wherein one or both of the first side cap and the second side cap are each adapted to substantially cover a respective one of the openings at the beginning of the extrusion and the end of the extrusion.

7. A housing for a hand-held electronic device in accordance with claim 5, wherein at least one of the first side cap and the second side cap includes one or more connectors for receiving and making electrical connection with an electronic circuit substrate.

8. A housing for a hand-held electronic device in accordance with claim 7, wherein one of the at least one of the first side cap and the second side cap includes at least a pair of connectors, each connector having one or more terminals, and one or more electrical conductors coupling one of the terminals from a first one of the pair of connectors to one of the terminals from a second one of the pair of connectors.

9. A housing for a hand-held electronic device in accordance with claim 8, wherein the pair of connectors are arranged relative to the one of the at least one of the first side cap and the second side cap for receiving a pair of electronic circuit substrates, which are positioned in a side by side arrangement, where the first electronic substrate is most proximate the second electronic substrate via respective edges of each of the first electronic substrate and the second electronic substrate.

10. A housing for a hand-held electronic device in accordance with claim 8, wherein the pair of connectors are arranged relative to the one of the at least one of the first side cap and the second side cap for receiving a pair of electronic circuit substrates, which are positioned in a substantially stacked parallel arrangement.

11. A housing for a hand-held electronic device in accordance with claim 7, wherein the electronic circuit substrate is received within or removed from the internal space via an opening in one of the first side cap and the second side cap.

12. A housing for a hand-held electronic device in accordance with claim 2, wherein one or more of the openings of the extruded element at each of the beginning and the end of the extrusion provides access to electronic circuitry located within the internal space of the extruded element.

13. A housing for a hand-held electronic device in accordance with claim 12, wherein the access is provided via one or more connector ports.

14. A housing for a hand-held electronic device in accordance with claim 2, wherein one or more of the openings of the extruded element at each of the beginning and the end of the extrusion provides access for inserting into or removing from the internal space one or more electronic circuits.

15. A housing for a hand-held electronic device in accordance with claim 14, wherein access for inserting into or removing from the internal space one or more electronic circuits occurs via a side cap coupled to the extruded element proximate the opening at one of the beginning and the end of the extrusion.

16. A housing for a hand-held electronic device in accordance with claim 14, wherein the one or more electronic circuits includes a battery.

17. A housing for a hand-held electronic device in accordance with claim 14, wherein the one or more electronic circuits includes a subscriber identity module (SIM).

18. A housing for a hand-held electronic device in accordance with claim 14, wherein the one or more electronic circuits includes a memory card.

19. A housing for a hand-held electronic device in accordance with claim 2, wherein one or more of the openings of the extruded element at each of the beginning and the end of the extrusion provides access to one or more user actuatable switches.

20. A hand-held electronic device including a housing comprising:
an extruded element having a length and a profile, the profile corresponding to a cross-section of the element, which is perpendicular to the direction of extrusion;
wherein the profile of the extruded element has a major axis which extends a distance in a first direction and a minor axis which extends a distance in a second direction which is substantially perpendicular to the first direction, and wherein the amount of the distance that the profile extends in the direction of the major axis is greater than the amount of the distance that the profile extends in the direction of the minor axis
wherein the length of the extruded element in the direction of extrusion is less than the amount of the distance that the profile extends in the direction of the major axis.
